(19) United States
(12) Patent Application Publication
(10) Pub. No.: US 2018/0210190 A1
(43) Pub. Date: Jul. 26, 2018

(54) MIRROR DEVICE

(71) Applicant: KYOCERA Corporation, Kyoto-shi, Kyoto (JP)

(72) Inventor: Hiroki OKADA, Kyoto-shi (JP)

(73) Assignee: KYOCERA Corporation, Kyoto-shi, Kyoto (JP)

(21) Appl. No.: 15/748,049

(22) PCT Filed: Jul. 21, 2016
(86) PCT No.: PCT/JP2016/071388

§ 371 Date: Jan. 26, 2018

(30) Foreign Application Priority Data
Jul. 27, 2015 (JP) 2015-147722

(51) Int. Cl. G02B 26/08; B81B 3/00

(52) U.S. Cl. CPC G02B 26/0858; B81B 2201/042; B81B 3/0045

(57) ABSTRACT

A mirror device includes a fixing section, mirror section, first connecting section, first beam section, second connecting section, and second beam section. The mirror section includes a major surface and a light reflecting surface. The first connecting section includes a first end connected to the mirror section and extends in a first direction from the first end. The first beam section connects the fixing section and the first connecting section and extends intersecting the first direction. The first beam section can be deformed by applying voltage. The second connecting section includes a second end connected to the first beam section and extends in the first direction from the second end on a virtual straight line extending in the first direction from the first end. The second beam section connects the fixing section and the second connecting section and extends intersecting the first direction, and can be deformed by applying voltage.

### TECHNICAL FIELD

The present invention relates to a mirror device capable of controlling an advancing direction of light.

### BACKGROUND ART

There is a mirror device which controls the advancing direction of light by changing the orientation of a mirror having a light reflecting surface. This mirror device is utilized in a copying machine, laser printer, display, barcode reader, communication-use optical switch, or other optical apparatus.

Such a mirror device is provided with a frame-shaped fixing section, a mirror section positioned inside the fixing section, main shaft sections (connecting sections) supporting the mirror section, beam-shaped movable frames (beam sections) which extend in a direction vertical with respect to the connecting sections, support the connecting sections in their central parts, and are connected to the fixing section at the two end parts, and piezoelectric elements provided on the beam sections. Further, by applying voltage to the piezoelectric elements, the beam sections can be made to curve to change the orientation of the mirror section (see Japanese Patent Publication No. 2009-2978A).

### SUMMARY OF INVENTION

A mirror device according to a first aspect of the present disclosure includes a fixing section, mirror section, first connecting section, first beam section, second connecting section, and second beam section. The mirror section includes a major surface and a light reflecting surface on the major surface. The first connecting section includes a first end connected to the mirror section and extends in a first direction from the first end. The first beam section connects the fixing section and the first connecting section and extends intersecting the first direction. Further, the first beam section can be deformed by applying voltage. The second connecting section includes a second end connected to the first beam section or the first connecting section and extends in the first direction from the second end on a virtual straight line extending in the first direction from the first end. The second beam section connects the fixing section and the second connecting section and extends intersecting the first direction. Further, the second beam section can be deformed by applying voltage.

A mirror device according to a second aspect of the present disclosure includes a fixing section, mirror section, first connecting section, first beam section, and second connecting section. The mirror section includes a major surface and a light reflecting surface on the major surface. The first connecting section includes a first end connected to the mirror section and extends in a first direction from the first end. The first beam section connects the fixing section and the first connecting section and extends intersecting the first direction. Further, the first beam section can be deformed by applying voltage. The second connecting section includes a second end connected to the first beam section or the first connecting section and extends in the first direction from the second end on the virtual straight line extending in the first direction from the first end. Further, the second connecting section can be deformed by applying voltage. The second beam section connects the fixing section and the second connecting section and extends intersecting the first direction.

A mirror device according to a third aspect of the present disclosure includes a fixing section, mirror section, first connecting section, first beam section, and second connecting section. The mirror section includes a major surface and a light reflecting surface on the major surface. The first connecting section includes a first end connected to the mirror section and extends in a first direction from the first end. The first beam section connects the fixing section and the first connecting section and extends intersecting the first direction. Further, the first beam section can be deformed by applying voltage. The second connecting section extends in the first direction on a virtual straight line extending in the first direction from the first end, and connects the fixing section and the first beam section. Further, the second connecting section can be deformed by applying voltage.

### BRIEF DESCRIPTION OF DRAWINGS

FIG. 1 A plan view of a mirror device of a first embodiment.

FIG. 2 A cross-sectional view of a mirror device taken along the II-II line in FIG. 1.

FIG. 3 A cross-sectional view of a mirror device taken along the III-III line in FIG. 1.

FIG. 4 A diagram showing an example of a control circuit using a mirror device.

FIG. 5 A plan view a mirror device of a second embodiment.

FIG. 6 A cross-sectional view of a mirror device taken along the VI-VI line in FIG. 5.

FIG. 7 A plan view a mirror device of a third embodiment.

FIG. 8 A cross-sectional view of a mirror device taken along the VIII-VIII line in FIG. 7.

FIG. 9 A plan view showing a modification of a mirror device.

FIG. 10 A cross-sectional view showing a modification of a mirror device.

### DESCRIPTION OF EMBODIMENTS

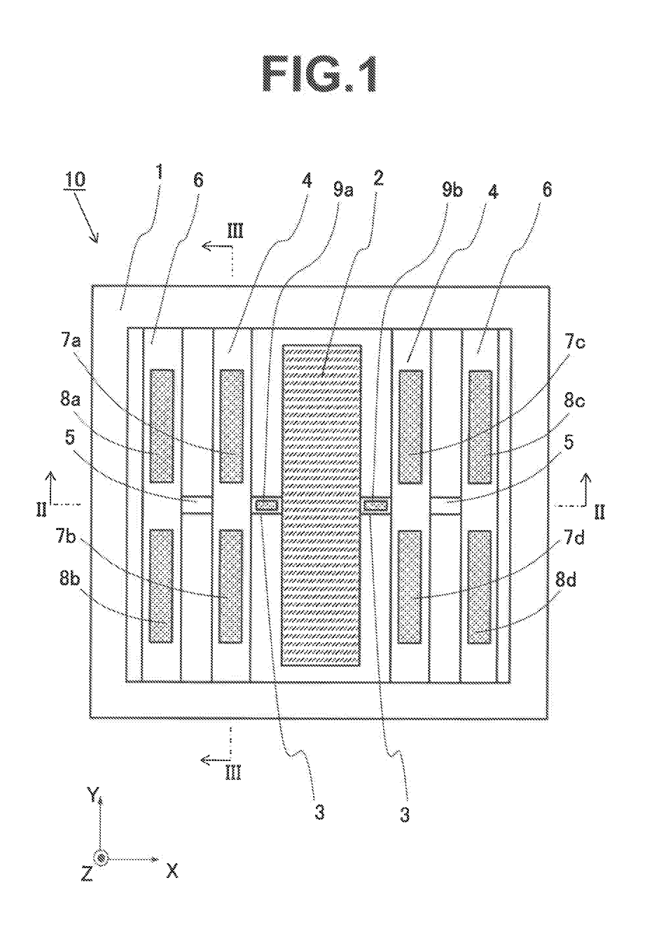

Various embodiments of a mirror device of the present disclosure will be explained with reference to the drawings. Note that, in FIG. 1 to FIG. 10, a right-hand XYZ coordinate systems is attached. In the following description, for convenience, the explanation will be given by defining the Z-axis direction as the up-down direction.

<Mirror Device in First Embodiment>

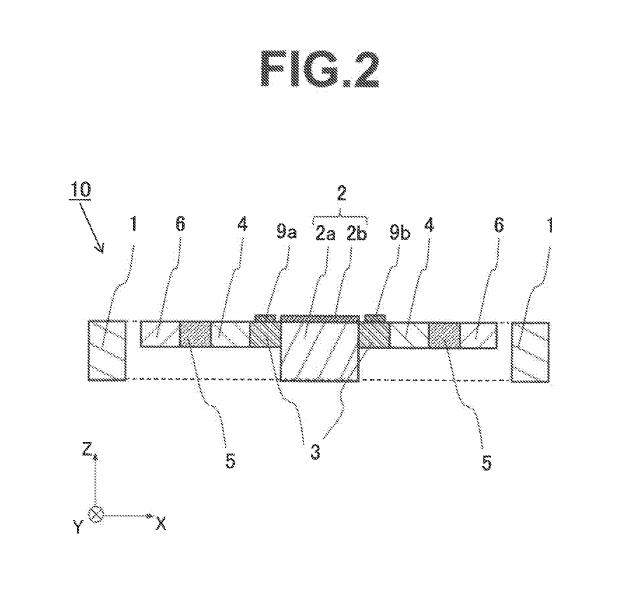

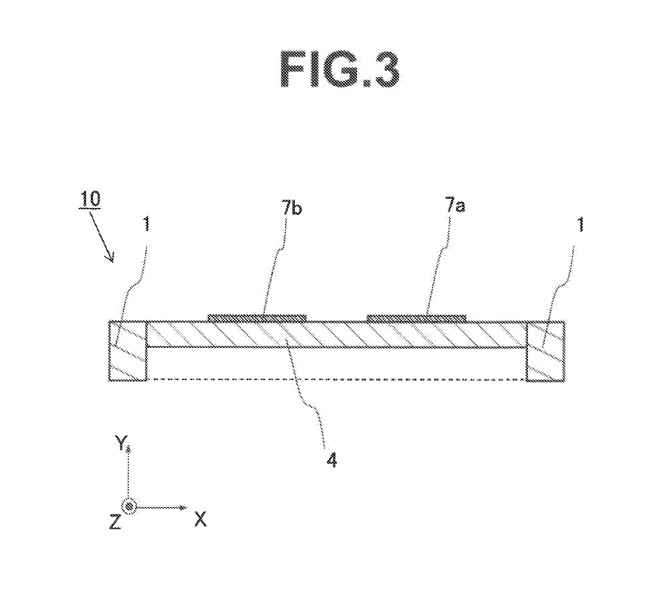

FIG. 1 is a plan view of a mirror device 10 of a first embodiment. Further, FIG. 2 is a cross-sectional view of the mirror device 10 taken along the II-II line in FIG. 1, while FIG. 3 is a cross-sectional view of the mirror device 10 taken along the line in FIG. 1. Below, the portions will be explained in detail.

The mirror device 10 is provided with a fixing section 1, mirror section 2, first connecting sections 3, first beam sections 4, second connecting sections 5, and second beam sections 6.

The fixing section 1 is for example a frame-shaped body having a rectangular shape, circular shape, or elliptical shape etc. in a plan view. FIG. 1 shows an example where the fixing section 1 is a frame-shaped body having a rectangular shape in a plan view. When the fixing section 1 is a frame-shaped body, the length of one side of the fixing section is for example 2 to 30 mm. Further, the width of the arms configuring the fixing section 1 (the width in the direction perpendicular to the longitudinal direction of the arms) is for example 0.2 to 6 mm. Further, the thickness of the fixing section 1 is for example 0.1 to 1 mm.

The mirror section 2 has a major surface (major surface on the +Z side in FIG. 1 to FIG. 3) and has a light reflecting surface on this major surface. The mirror section 2, for example, as shown in FIG. 2, may be provided with a support member 2a having a major surface and a light reflecting member 2b which is positioned on that major surface and has a high optical reflection coefficient such as a thin metal film.

The shape of the mirror section 2 when viewed on a plane is for example a rectangular shape, circular shape, or elliptical shape etc. FIG. 1 shows an example where the shape of the mirror section 2 in a plan view is a rectangular shape. When the shape of the mirror section 2 in a plan view is rectangular, the length of one side (side extending in the Y-axis direction) of the mirror section 2 to which a first connecting section 3 is connected, is for example 1 to 10 mm. Further, the length perpendicular to the above one side (side extending in the X-axis direction) is for example 0.3 to 1 mm.

The first connecting sections 3 are connected at single ends (hereinafter, referred to as the “first ends”) to the mirror section 2. Further, the first connecting sections 3 extend in the first direction (X-axis direction) from these first ends and are connected at the other ends on the opposite sides to the first ends to the first beam sections 4. The first connecting sections 3 have a function of changing the orientation of the mirror section 2 by rotating motion about the first direction so as to follow deformation of the first beam sections 4 due to application of voltage.

In the first connecting sections 3, from the viewpoint of moving the mirror section 2 well following deformation of the first beam sections 4, the width in the Y-axis direction when viewed on a plane is for example 0.01 to 0.1 mm, the length in the X-axis direction is for example 0.10 to 2 mm, and the thickness is for example 0.01 to 0.3 mm. Further, the shape of the cross-section (YZ cross-section) perpendicular to the X-axis direction in the first connecting sections 3 is not particularly limited and may be a polygonal shape, circular shape, elliptical shape, etc.

The first beam sections 4 connect the fixing section 1 and the first connecting sections 3 and extend so as to intersect the first direction (X-axis direction). In FIG. 1, the first beam sections 4 extend from the connected portions with the first connecting sections 3 to two directions of the +Y direction and −Y direction and are connected to the pair of arms of the fixing section 1 which face each other. Note that, the first beam sections 4 are not limited to such a configuration and may be configured so that they are connected with only one arm of the fixing section 1 from the connected portion with the first connecting section 3 as well. Further, an angle formed by the first beam sections 4 and the X-axis need not be 90° as shown in FIG. 1, but may be an acute angle or obtuse angle.

The beam sections 4 have structures that can be deformed by applying voltage. Such structures, as shown in FIG. 1 and FIG. 3, may be structures in which piezoelectric elements 7a to 7d are provided on the surfaces (upper surfaces in FIG. 1) of main bodies of the first beam sections 4. As the piezoelectric elements 7a to 7d, for example there can be mentioned ones having electrodes on piezoelectric films. By applying voltage through these electrodes to the piezoelectric films, distortion is caused in the piezoelectric films. As a result, it becomes possible to make the entire first beam sections 4 deform. Note that, in the piezoelectric elements formed on the upper surfaces of the beam sections 4, the piezoelectric films may be formed on the entire upper surfaces of the first beam sections 4 as well. In these piezoelectric films, the portions which can be given voltage by the electrodes function as piezoelectric elements.

In the first beam sections 4, from the viewpoint of moving the mirror section 2 well, the widths when viewed on a plane (lengths in the X-axis direction) are for example 0.05 to 0.5 mm, and the thicknesses are for example 0.01 to 0.3 mm. The shapes of the first beam sections 4 in a plan view are not limited to straight shapes and may be curved shapes or rectangular shapes. The shapes of the cross-sections (XZ cross-sections) of the first beam sections 4 vertical to the extension direction (Y-axis direction) are not particularly limited and may be polygonal shapes, circular shapes, elliptical shapes, or the like.

When defining an imaginary straight line extending in the first direction (X-axis direction) from the above first ends of the first connecting sections 3 as a virtual straight line, second connecting sections 5 are connected in single ends (below, referred to as the “second ends”) on this virtual straight line to the first beam sections 4 or first connecting sections 3. Further, on the virtual straight line, the second connecting sections 5 extend in the first direction from these second ends.

Further, the second beam sections 6 connect the fixing section 1 and the second connecting sections 5 and extend so as to intersect the first direction. Further, the second beam sections 6 can be deformed by application of voltage.

By providing such second connecting sections 5 and second beam sections 6, it becomes possible to change the resonant frequencies of the mirror section 2 and the first connecting sections 3, therefore the precision of the mirror device 10 can be maintained high. That is, by making the second beam sections 6 deform, tensile stress or compression stress can be applied to the mirror section 2 and the first connecting sections 3 to change the rigidities of the first connecting sections 3 and it becomes possible to control the resonant frequencies of the mirror section 2 and the first connecting sections 3. As a result, even in a case where heat or distortion is generated in the mirror device 10 at the time when the mirror device 10 is driven or according to the driving environment, the drive frequencies applied to the piezoelectric elements 7a to 7d and the resonant frequency of the mirror section 2 can be maintained at the same extent.

In a mirror device such as shown in Patent Literature 1, when the resonant frequency of the mirror member and the drive frequencies of the electrical signals which are applied to the piezoelectric elements are the same, the displacement of the mirror section becomes the maximum. However, in a case where heat or distortion is generated in the mirror device at the time of driving the mirror device or according to the driving environment, the resonant frequency fluctuates, therefore there is a difference from the drive frequencies. As a result, the precision of the mirror device easily falls. Contrary to this, the mirror device 10 in the first embodiment can maintain the precision high as explained above.

The second connecting sections 5 have the function of adding a compression stress or tensile stress to the mirror section 2 and the first connecting sections 3 well by moving along the first direction (X-axis direction) following deformation of the second beam sections 6 due to application of voltage. In the second connecting section 5, the width of the direction perpendicular to the first direction when viewed on a plane (width of the Y-axis direction) is for example 0.02 to 0.4 mm, the length of the X-axis direction is for example 0.02 to 1 mm, and the thickness is for example 0.01 to 0.3 mm. Further, the shape of the cross-section (YZ cross-section) at the second connecting section 5 vertical to the X-axis direction is not particularly limited and may be a polygonal shape, circular shape, elliptical shape, or the like.

From the viewpoint of improving the deformation of the first beam sections 4 by application of voltage while controlling the resonant frequency of the mirror section 2 by deformation of the second connecting sections 5 well, in the second connecting sections 5, the widths in the direction perpendicular to the first direction when viewed on a plane (widths in the Y-axis direction) may be 0.01 to 0.1 time the lengths of the first beam sections 4 in the Y-axis direction as well. With such widths, transfer of stress by the second connecting sections 5 to the entire first beam sections 4 can be reduced, therefore the precision of deformation of the first beam sections 4 by application of voltage can be maintained well.

Further, in the case of a configuration where the first beam sections 4 have the piezoelectric elements 7a to 7d as shown in FIG. 1, it may be a configuration where the piezoelectric elements 7a to 7d are not arranged in the vicinities of the portions of the first beam sections 4 connected with the second connecting sections 5. Due to this configuration, transfer of stress by the second connecting sections 5 to the piezoelectric elements 7a to 7d can be reduced, therefore the precision of deformation of the first beam sections 4 by application of voltage can be maintained better.

The second beam sections 6 connect the fixing section 1 and the second connecting sections 5 and extend so as to intersect the first direction (X-axis direction). In FIG. 1, the second beam sections 6 extend from the portions connected with the second connecting sections 5 to the two directions of the +Y direction and −Y direction and are connected to the pair of arms of the fixing section 1 which face each other. Note that, the second beam sections 6 are not limited to such a configuration and may be configured so that they are connected with only one arm from the connected portions with the second connecting sections 5 as well. Further, the angles formed by the second beam sections 6 and the X-axis need not be 90° as shown in FIG. 1 but may be acute angles or obtuse angles.

The second beam sections 6 have structures in which deformation is possible by applying voltage. Such structures, as shown in FIG. 1, may be structures in which piezoelectric elements 8a to 8d are provided on the surfaces (upper surfaces in FIG. 1) of the main bodies of the second beam sections 6 as well. As the piezoelectric elements 8a to 8d, for example, there can be mentioned ones having electrodes on piezoelectric films. By applying voltage through these electrodes to the piezoelectric films, distortion is caused in the piezoelectric films. As a result, it becomes possible to make the entire second beam sections 6 deform. As such piezoelectric film, use may be made of barium titanate, lead zirconate titanate (PZT), or the like.

From a viewpoint of controlling the resonant frequency of the mirror section 2 well, in the second beam sections 6, the widths when viewed on a plane (lengths in the X-axis direction) are for example 0.05 to 0.5 mm, and the thicknesses are for example 0.01 to 0.3 mm. The shapes of the second beam sections 6 in a plan view are not limited to straight shapes and may be curved shapes or rectangular shapes. The shapes of the cross-sections (XZ cross-sections) of the second beam sections 6 vertical to the extension direction (Y-axis direction) are not particularly limited and may be polygonal shapes, circular shapes, elliptical shapes, or the like.

Further, the first connecting sections 3, as shown in FIG. 1, may have structures in which piezoelectric elements 9a and 9b are further provided on the surfaces (upper surfaces in FIG. 1) of the first connecting sections 3 as well. As the piezoelectric elements 9a and 9b, for example there can be mentioned ones having electrodes on piezoelectric films. The piezoelectric elements 9a and 9b function as sensors for reading amounts of deformation of the first connecting sections 3. That is, due to the deformation of the first connecting sections 3, the piezoelectric elements 9a and 9b warp. The amounts of deformation can be read from voltages generated by this.

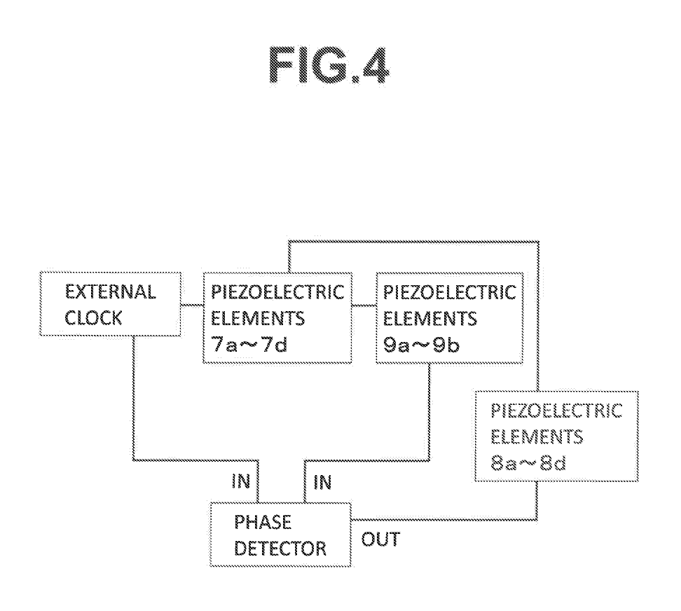

The piezoelectric elements 9a and 9b used as such sensors, the piezoelectric elements 7a to 7d deforming the first connecting sections 3, and the piezoelectric elements 8a to 8d deforming the second beam sections 6 are for example driven by a control circuit as shown in FIG. 4. In FIG. 4, clock signals are input from an external clock to the piezoelectric elements 7a to 7d. The amounts of deformation of the first connecting sections 3 are detected by the piezoelectric elements 9a and 9b. Further, a phase detector positioned outside or inside of the mirror device 10 reads phases of outputs from the piezoelectric elements 9a and 9b and detects a phase difference from the external clock. By applying a voltage corresponding to this phase difference to the piezoelectric elements 8a to 8d, the second beam sections 6 deform, and the phase difference is automatically controlled to become a desired phase difference (resonant phase in this case). Due to this, the resonant frequencies of the mirror section 2 and the first connecting sections 3 can be automatically made to match with the frequency of the external clock. As a result, in the control circuit, although the external clock is used, a driving at the resonant frequency is always executed, so the driving voltage does not become large, therefore low-voltage operation becomes possible.

The mirror device 10 can be prepared in the following way. First, a substrate made of silicon or the like is processed by using a known semiconductor fine processing method to integrally form the fixing section 1, mirror section 2, first connecting sections 3, main bodies of the first beam sections 4, and main bodies of the second connecting sections 5 and second beam sections 6. Next, the upper surfaces of the main bodies of the first beam sections 4 and main bodies of the second beam sections 6 are formed with electrodes and piezoelectric films using a known thin film forming method to prepare piezoelectric elements 7a to 7d, 8a to 8d, and 9a and 9b. By this, the mirror device 10 is completed.

<Mirror Device of Second Embodiment>

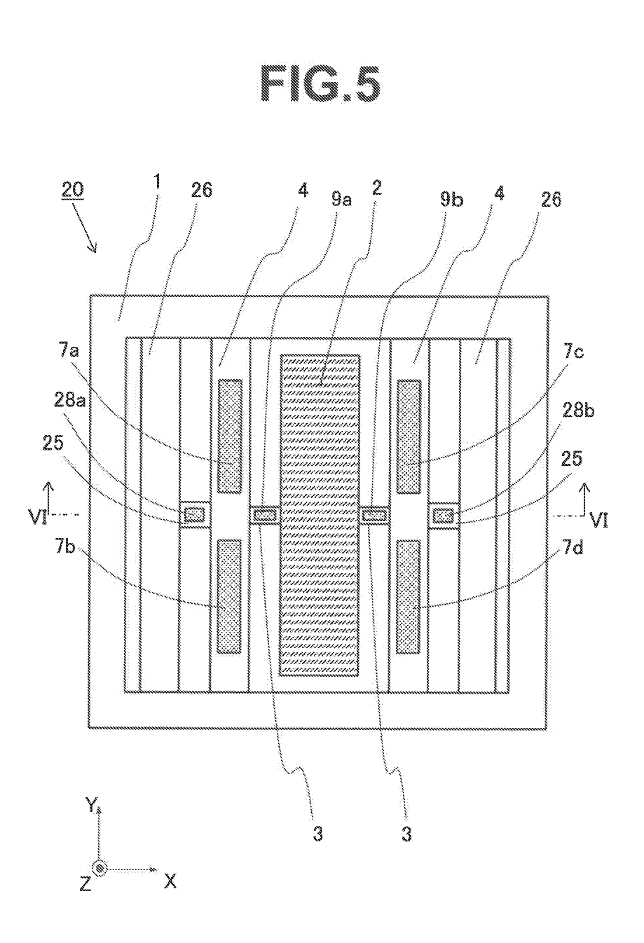

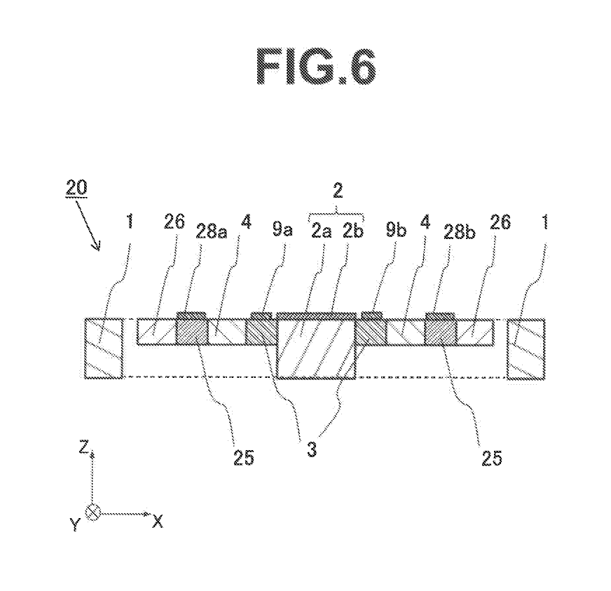

FIG. 5 is a plan view of a mirror device 20 of a second embodiment. Further, FIG. 6 is a cross-sectional view of the mirror device 20 taken along the VI-VI line in FIG. 5. In the mirror device 20, parts having the same configurations as those in the mirror device 10 shown in FIG. 1 to FIG. 3 are assigned the same notations and detailed explanations are omitted.

The mirror device 20 differs from the mirror device 10 in the point that deformation of the second connecting sections 25 becomes possible by applying voltage. In the example shown in FIG. 5 and FIG. 6, piezoelectric elements 28 are positioned not on the second beam sections 26, but on the surfaces of the main bodies of the second connecting sections 25.

According to such a configuration, it becomes possible to change the resonant frequencies of the mirror section 2 and the first connecting sections 3, therefore the precision of the mirror device 20 can be maintained high. That is, by deformation of the second connecting sections 25, tensile stress or compression stress is applied with respect to the mirror section 2 and the first connecting sections 3, thus the rigidity of the first connecting sections 3 can be changed. Therefore, it becomes possible to control the resonant frequencies of the mirror section 2 and the first connecting sections 3. As a result, even in a case where heat or distortion is generated in the mirror device 20 at the time of driving the mirror device 20 or according to the driving environment, the drive frequencies applied to the piezoelectric elements 7a to 7d and the resonant frequency of the mirror section 2 can be maintained to the same extent.

When defining an imaginary straight line extending in the first direction (X-axis direction) from the above first ends of the first connecting sections 3 (ends of the first connecting sections 3 connected to the mirror section 2) as the virtual straight line, second connecting sections 25 are connected at single ends (below, referred to as the “second ends”) on this virtual straight line to the first beam sections 4 or first connecting sections 3. Further, on the virtual straight line, the second connecting sections 25 extend in the first direction from these second ends.

Further, the second connecting sections 25 have structures in which deformation is possible by applying voltage. Such structures, as shown in FIG. 5 and FIG. 6, may be structures in which piezoelectric elements 28a and 28b are provided on the surfaces (upper surfaces in FIG. 5) of the main bodies of the second connecting sections 25 as well. As the piezoelectric elements 28a and 28b, for example, there can be mentioned ones having electrodes on piezoelectric films. By applying voltage through these electrodes to the piezoelectric films, distortion is caused in the piezoelectric films. As a result, it becomes possible to make the entire second connecting sections 25 deform. Note that, the shapes of the main bodies of the second connecting sections 25 may be made the same as the shapes of the second connecting sections 5 used in the mirror device 10.

The second beam sections 26 connect the fixing section 1 and the second connecting sections 25 and extend so as to intersect the first direction (X-axis direction). Note that, the shapes of the second beam sections 26 can be made the same as the shapes of the main bodies of the second beam sections 6 used in the mirror device 10. Piezoelectric elements may be further provided on the surfaces of these second beam sections 26 as well. In this case, the drive frequencies applied to the piezoelectric elements 7a to 7d, and the resonant frequency of the mirror section 2 can be maintained to the same extent better.

<Mirror Device of Third Embodiment>

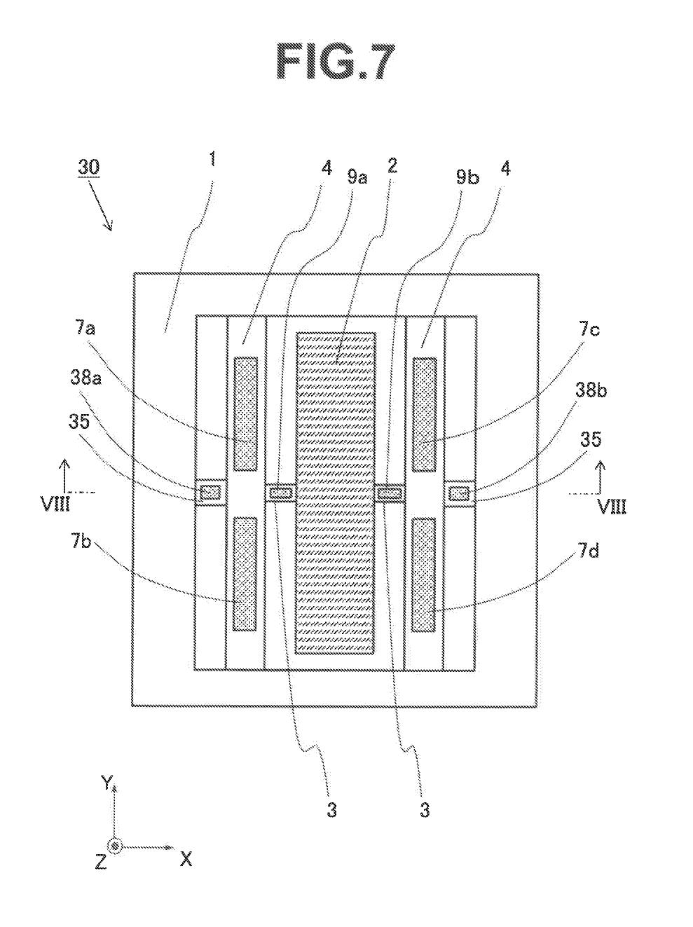

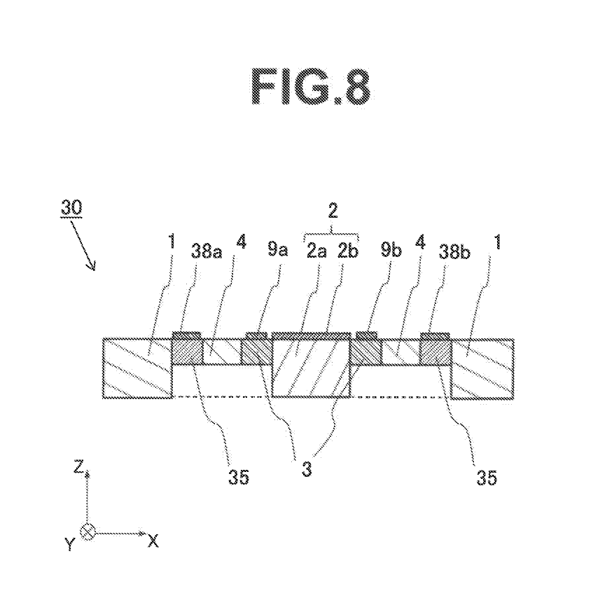

FIG. 7 is a plan view of a mirror device 30 of a third embodiment. Further, FIG. 8 is a cross-sectional view of the mirror device 30 taken along the VIII-VIII line in FIG. 7. In the mirror device 30, parts having the same configurations as those in the mirror device 10 shown in FIG. 1 to FIG. 3 are assigned the same notations and detailed explanations are omitted.

The mirror device 30 differs from the mirror device 10 in the point that the second beam sections are not provided, the second connecting sections 35 connect the first beam sections 4 and the fixing section 1, and the second connecting sections 35 become able to deform by applying voltage. In the example in FIG. 7 and FIG. 8, piezoelectric elements 38 are positioned on the surfaces of the main bodies of the second connecting sections 35.

According to such a configuration, it becomes possible to change the resonant frequencies of the mirror section 2 and the first connecting sections 3, therefore the precision of the mirror device 30 can be maintained high. That is, by deforming the second connecting sections 35, tensile stress or compression stress is applied with respect to the mirror section 2 and the first connecting sections 3 and the rigidity of the first connecting sections 3 can be changed, so it becomes possible to control the resonant frequencies of the mirror section 2 and the first connecting sections 3. As a result, even in a case where heat or distortion is generated in the mirror device 30 at the time of driving the mirror device 30 or according to the driving environment, the drive frequencies applied to the piezoelectric elements 7a to 7d and the resonant frequency of the mirror section 2 can be maintained to the same extent.

When defining an imaginary straight line extending in the first direction (X-axis direction) from the above first ends of the first connecting sections 3 (ends of the first connecting sections 3 connected with the mirror section 2) as the virtual straight line, second connecting sections 35 are connected at single ends (below, referred to as the “second ends”) on this virtual straight line to the first beam sections 4 or first connecting sections 3. Further, on the virtual straight line, the second connecting sections 35 extend in the first direction from these second ends.

Further, the second connecting sections 35 have structures in which deformation is possible by applying voltage. Such structures, as shown in FIG. 7 and FIG. 8, may be structures in which piezoelectric elements 38a and 38b are provided on the surfaces (upper surfaces in FIG. 7) of the main bodies of the second connecting sections 35 as well. As the piezoelectric elements 38a and 38b, for example, there can be mentioned ones having electrodes on piezoelectric films. By applying voltage through these electrodes to the piezoelectric films, distortion is caused in the piezoelectric films. As a result, it becomes possible to make the entire second connecting sections 35 deform. Note that, the shapes of the second connecting sections 35 may be made the same as the shapes of the second connecting sections 5 used in the mirror device 10.

<Modification of Mirror Devices of First to Third Embodiments>

The present invention is not limited to the embodiments explained above. Various alterations and improvements etc. are possible insofar as they are not out of the gist of the present invention. For example, in any of the mirror devices 10, 20, and 30 in the first to third embodiments, the rigidities of the second connecting sections may be higher than the rigidities of the first connecting sections as well. In that case, the control of the resonant frequencies of the mirror section 2 and first connecting sections 3 by the second beam sections 6 or second connecting sections 25 or 35 can be more efficiently carried out, and a lower voltage operation becomes possible.

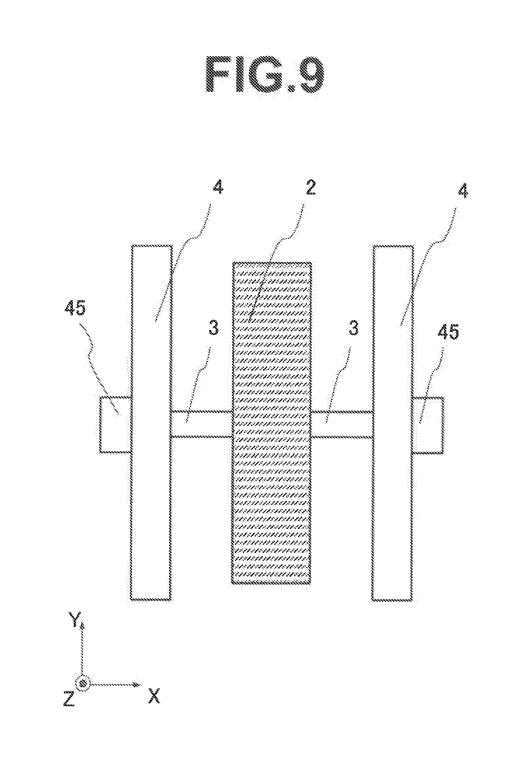

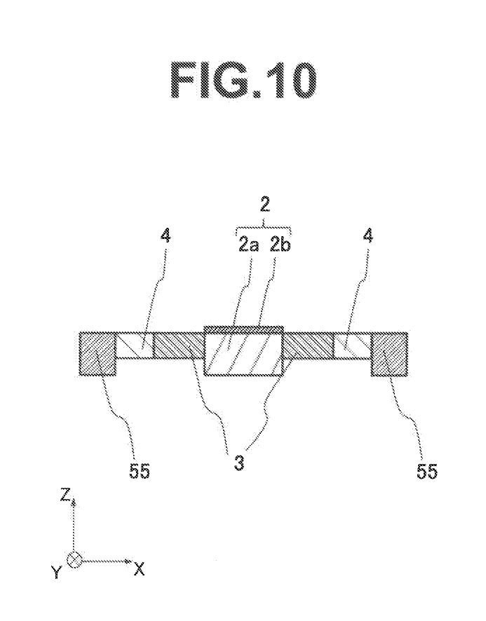

As a method of making the rigidities of the second connecting sections higher than the rigidities of the first connecting sections, for example, use may be made of a material having a higher elastic modulus than the first connecting sections. Alternatively, the cross-sectional areas at the cross-sections (YZ cross-section) vertical to the first direction in the second connecting sections may be made larger than those of the first connecting sections as well. As a method of making the cross-sectional areas larger, as shown in the modification in FIG. 9, the widths in the Y-axis direction of the second connecting sections 45 may be made larger than those in the first connecting sections 3 as well. Alternatively, as shown in the modification in FIG. 10, the thicknesses in the Z-axis direction of the second connecting sections 55 may be made greater than those in the first connecting sections 3 as well. So far as such second connecting sections 45 or second connecting sections 55 are employed, the main body of the mirror section 2, the first connecting sections 3, first beam sections 4, and second connecting sections 45 or 55 can be integrally prepared from one member, the manufacturing process is easy, and low-voltage operation becomes possible.

### REFERENCE SIGNS LIST

1: fixing section
2: mirror section
3: first connecting section
4: first beam section
5, 25, 35: second connecting sections
6, 26: second beam sections
10, 20, 30: mirror devices

1. A mirror device comprising:
a fixing section,
a mirror section which comprises a major surface and a light reflecting surface on the major surface,
a first connecting section which comprises a first end connected to the mirror section and extends in a first direction from the first end,
a first beam section which connects the fixing section and the first connecting section and extends intersecting the first direction and which can be deformed by applying voltage,
a second connecting section which comprises a second end connected to the first beam section or the first connecting section and extends in the first direction from the second end on a virtual straight line extending in the first direction from the first end, and
a second beam section which connects the fixing section and the second connecting section and extends intersecting the first direction and which can be deformed by applying voltage.

2. The mirror device according to claim 1, wherein the second connecting section has a higher rigidity than that of the first connecting section.

3. The mirror device according to claim 2, wherein the second connecting section has a larger cross-sectional area at a cross-section vertical to the first direction than that of the first connecting section.

4. A mirror device comprising:
a fixing section,
a mirror section which comprises a major surface and a light reflecting surface on the major surface,
a first connecting section which comprises a first end connected to the mirror section and extends in a first direction from the first end,
a first beam section which connects the fixing section and the first connecting section and extends intersecting the first direction and which can be deformed by applying voltage,
a second connecting section which comprises a second end connected to the first beam section or the first connecting section and extends in the first direction from the second end on a virtual straight line extending in the first direction from the first end and which can be deformed by applying voltage, and
a second beam section which connects the fixing section and the second connecting section and extends intersecting the first direction.

5. The mirror device according to claim 4, wherein the second connecting section has a higher rigidity than that of the first connecting section.

6. The mirror device according to claim 5, wherein the second connecting section has a larger cross-sectional area at a cross-section vertical to the first direction than that of the first connecting section.

7. A mirror device comprising:
a fixing section,
a mirror section which comprises a major surface and a light reflecting surface on the major surface,
a first connecting section which comprises a first end connected to the mirror section and extends in a first direction from the first end,
a first beam section which connects the fixing section and the first connecting section and extends intersecting the first direction and which can be deformed by applying voltage, and
a second connecting section which extends in the first direction on a virtual straight line extending in the first direction from the first end, and connects the fixing section and the first beam section and which can be deformed by applying voltage.

8. The mirror device according to claim 7, wherein the second connecting section has a higher rigidity than that of the first connecting section.

9. The mirror device according to claim 8, wherein the second connecting section has a larger cross-sectional area at cross-section vertical to the first direction than that of the first connecting section.
